(19) United States
(12) Patent Application Publication
(10) Pub. No.: US 2025/0130498 A1
(43) Pub. Date: Apr. 24, 2025

(54) RESIST UNDERLAYER FILM FORMATION COMPOSITION, RESIST PATTERN FORMATION METHOD, FORMATION METHOD FOR RESIST UNDERLAYER FILM PATTERN, AND PATTERN FORMATION METHOD

(71) Applicant: TOKYO OHKA KOGYO CO., LTD., Kawasaki-shi (JP)

(72) Inventors: Keiichi Ibata, Kawasaki-shi (JP); Masaru Takeshita, Kawasaki-shi (JP)

(21) Appl. No.: 18/725,992

(22) PCT Filed: Dec. 22, 2022
(86) PCT No.: PCT/JP2022/047449

§ 371 Date: Jul. 1, 2024

(30) Foreign Application Priority Data
Jan. 7, 2022 (JP) 2022-001560

(51) Int. Cl. G03F 7/09; G03F 7/20

(52) U.S. Cl. CPC G03F 7/091; G03F 7/20

(57) ABSTRACT

A composition for forming a resist underlayer film, including a furan resin, a thermal acid generator component that generates an acid by heat, and a solvent; a resist pattern formation method including forming a resist underlayer film on a substrate using the composition, forming a resist film on the resist underlayer film using the resist composition, exposing the resist film to light, and developing the resist film exposed to light to form a resist pattern; and a formation method for a resist underlayer film pattern and a pattern formation method, including the resist pattern formation method.

### TECHNICAL FIELD

The present invention relates to a composition for forming a resist underlayer film, a resist pattern formation method, a formation method for a resist underlayer film pattern, and a pattern formation method.

Priority is claimed on Japanese Patent Application No. 2022-001560, filed Jan. 7, 2022, the content of which is incorporated herein by reference.

### BACKGROUND ART

A lithography method is used for manufacturing fine structures in various electronic devices such as a semiconductor device and a liquid crystal device. In recent years, with the miniaturization of device structures, there has been a demand for miniaturization of resist patterns in lithography steps.

In a case where a resist film is exposed to light, an antireflective film is used between the resist film and a substrate in order to suppress reflected light from the substrate. However, an antireflective film is typically a thin film with a thickness of several tens of nanometers and thus cannot be used as a mask during dry etching of a substrate. Therefore, it is necessary to form an underlayer film for a mask on an underlayer of the antireflective film.

A resist underlayer film that has an antireflection function and can be used as a mask during dry etching has also been examined. For example, Patent Document 1 describes a composition for a resist underlayer film, which contains a copolymer having a constitutional unit derived from an acrylic monomer having an adamantyl group in a side chain and a constitutional unit derived from a hydroxystyrene derivative.

### CITATION LIST

### Patent Document

[Patent Document 1] Japanese Unexamined Patent Application, First Publication No. 2007-240630

### SUMMARY OF INVENTION

### Technical Problem

It cannot be said that a composition for forming a resist underlayer film in the related art as described in Patent Document 1 has a sufficient antireflection function. Meanwhile, in a case where the antireflection function is increased, the etching resistance is decreased, and the performance of the composition as a mask during dry etching is degraded. In order to form a satisfactory resist pattern and to satisfactorily perform dry etching on a substrate, two layers, an antireflective film and an underlayer film for a mask, are required, and thus the steps are complicated. The steps can be simplified in a case where a resist underlayer film that has an excellent antireflection function and can be used as a mask during dry etching can be formed.

The present invention has been made in consideration of the above-described circumstances, and an object thereof is to provide a composition for forming a resist underlayer film that has an excellent antireflection function and can be used as a mask during dry etching, and a resist pattern formation method, a formation method for a resist underlayer film pattern, and a pattern formation method using the composition for forming a resist underlayer film.

### Solution to Problem

In order to achieve the above-described object, the present invention employs the following configurations.

According to a first aspect of the present invention, there is provided a composition for forming a resist underlayer film, including: a furan resin; a thermal acid generator component that generates an acid by heat; and a solvent.

According to a second aspect of the present invention, there is provided a resist pattern formation method including: a step of forming a resist underlayer film on a substrate using the composition for forming a resist underlayer film according to the first aspect; a step of forming a resist film on the resist underlayer film using a resist composition; a step of exposing the resist film to light; and a step of developing the resist film exposed to light to form a resist pattern.

According to a third aspect of the present invention, there is provided a formation method for a resist underlayer film pattern, including: a step of forming a resist pattern by the resist pattern formation method according to the second aspect; and a step of etching the resist underlayer film using the resist pattern as a mask to form a resist underlayer film pattern.

According to a fourth aspect of the present invention, there is provided a pattern formation method including: a step of forming a resist underlayer film pattern by the formation method for a resist underlayer film pattern according to the third aspect; and a step of etching the substrate using the resist pattern and the resist underlayer film pattern as a mask to form a pattern.

### Advantageous Effects of Invention

According to the present invention, it is possible to provide a composition for forming a resist underlayer film that has an excellent antireflection function and can be used as a mask during dry etching, and a resist pattern formation method, a formation method for a resist underlayer film pattern, and a pattern formation method using the composition for forming a resist underlayer film.

### BRIEF DESCRIPTION OF DRAWINGS

FIG. 1 shows a step of a resist pattern formation method according to an embodiment.

FIG. 2 shows a step of a resist pattern formation method according to an embodiment.

FIG. 3 shows a step of a resist pattern formation method according to an embodiment.

FIG. 4 shows a step of a formation method for a resist underlayer film pattern according to an embodiment.

FIG. 5 shows a step of a pattern formation method according to an embodiment.

FIG. 6 shows a step of a pattern formation method according to an embodiment.

### DESCRIPTION OF EMBODIMENTS

In the present specification and the scope of the present claims, the term “aliphatic” is a relative concept used in relation to the term “aromatic”, and defines a group or compound that has no aromaticity.

The term “alkyl group” includes a linear, branched, or cyclic monovalent saturated hydrocarbon group unless otherwise specified. The same applies to the alkyl group in an alkoxy group.

The term “alkylene group” includes a linear, branched, or cyclic divalent saturated hydrocarbon group unless otherwise specified.

Examples of “halogen atom” include a fluorine atom, a chlorine atom, a bromine atom, and an iodine atom.

The term “constitutional unit” denotes a monomer unit constituting a polymer compound (a resin, a polymer, or a copolymer).

The expression “may have a substituent” includes both a case where a hydrogen atom (—H) is substituted with a monovalent group and a case where a methylene group (—CH₂—) is substituted with a divalent group.

The term “light exposure” is a general concept for irradiation with radiation.

The term “acid decomposable group” indicates a group having acid decomposability in which at least a part of a bond in the structure of the acid decomposable group can be cleaved due to the action of an acid.

Examples of the acid decomposable group whose polarity is increased due to the action of an acid include groups which are decomposed due to the action of an acid to generate a polar group.

Examples of the polar group include a carboxy group, a hydroxyl group, an amino group, and a sulfo group (—SO₃H).

More specific examples of the acid decomposable group include a group in which the above-described polar group has been protected by an acid dissociable group (such as a group in which a hydrogen atom of the OH-containing polar group has been protected by an acid dissociable group).

Here, the term “acid dissociable group” indicates both a group (i) having an acid dissociation property in which a bond between the acid dissociable group and an atom adjacent to the acid dissociable group can be cleaved due to the action of an acid and a group (ii) in which some bonds are cleaved due to the action of an acid, a decarboxylation reaction occurs, and thus the bond between the acid dissociable group and the atom adjacent to the acid dissociable group can be cleaved.

It is necessary that the acid dissociable group that constitutes the acid decomposable group is a group which exhibits a lower polarity than that of the polar group generated by the dissociation of the acid dissociable group. Thus, in a case where the acid dissociable group is dissociated due to the action of an acid, a polar group exhibiting a higher polarity than that of the acid dissociable group is generated so that the polarity is increased. As a result, the polarity of an entire component (A1) is increased. Due to the increase in the polarity, relatively, the solubility in a developing solution is changed such that the solubility is increased in a case where the developing solution is an alkali developing solution and the solubility is decreased in a case where the developing solution is an organic developing solution.

The term “base material component” denotes an organic compound having a film-forming ability. Organic compounds used as the base material component are classified into non-polymers and polymers. As the non-polymers, those having a molecular weight of 500 or greater and less than 4,000 are typically used. Hereinafter, the term “low-molecular-weight compound” denotes a non-polymer having a molecular weight of 500 or greater and less than 4,000. As the polymer, those having a molecular weight of 1,000 or greater are typically used. Hereinafter, “resin”, “polymer compound”, or “polymer” denotes a polymer having a molecular weight of 1,000 or greater. As the molecular weight of the polymer, the weight-average molecular weight in terms of polystyrene according to gel permeation chromatography (GPC) is used.

The expression “constitutional unit to be derived” denotes a constitutional unit formed by cleavage of a multiple bond between carbon atoms, for example, an ethylenic double bond.

In “acrylic acid ester”, the hydrogen atom bonded to the carbon atom at the α-position may be substituted with a substituent. The substituent (R^{αx}) that substitutes the hydrogen atom bonded to the carbon atom at the α-position is an atom other than the hydrogen atom or a group. Further, the acrylic acid ester includes itaconic acid diester in which the substituent (R^{αx}) has been substituted with a substituent having an ester bond and α-hydroxyacryl ester in which the substituent (R^{αx}) has been substituted with a hydroxyalkyl group or a group obtained by modifying a hydroxyl group thereof. Further, the carbon atom at the α-position of acrylic acid ester indicates the carbon atom to which the carbonyl group of acrylic acid is bonded, unless otherwise specified.

Hereinafter, acrylic acid ester in which the hydrogen atom bonded to the carbon atom at the α-position has been substituted with a substituent is also referred to as α-substituted acrylic acid ester.

The concept “derivative” includes those obtained by substituting a hydrogen atom at the α-position of a target compound with another substituent such as an alkyl group or a halogenated alkyl group, and derivatives thereof. Examples of the derivatives thereof include those obtained by substituting a hydrogen atom of a hydroxyl group of a target compound, in which the hydrogen atom at the α-position may be substituted with a substituent, with an organic group, and those obtained by bonding a substituent other than a hydroxyl group to a target compound in which the hydrogen atom at the α-position may be substituted with a substituent. Further, the α-position denotes the first carbon atom adjacent to a functional group unless otherwise specified.

Examples of the substituent that substitutes the hydrogen atom at the α-position of hydroxystyrene include those for R^{αx}.

In the present specification and the scope of the present claims, asymmetric carbons may be present and enantiomers or diastereomers may be present depending on the structures of the chemical formulae. In this case, these isomers are represented by one chemical formula. These isomers may be used alone or in the form of a mixture.

### (Composition for Forming Resist Underlayer Film)

A first aspect of the present invention relates to a composition for forming a resist underlayer film. The composition for forming a resist underlayer film according to the present aspect contains a furan resin, a thermal acid generator component that generates an acid by heat, and a solvent.

### <Resin Component: Component (A0)>

The composition for forming a resist underlayer film according to the present embodiment contains a furan resin (hereinafter, also referred to as “component (A01)”) as a resin component.

### <<Furan Resin: Component (A01)>>

The furan resin is a resin having a furan ring in the main chain. It is preferable that the furan resin has a constitutional unit represented by Formula (a01-1).

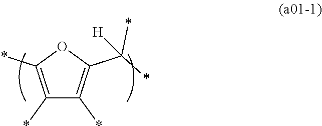

[In the formula, * represents a hydrogen atom, a substituent, or a bonding site with respect to an adjacent constitutional unit.]

In Formula (a0-1), * represents a hydrogen atom, a substituent, or a bonding site with respect to an adjacent constitutional unit. The substituent is not particularly limited.

The furan resin can be obtained by polymerizing a monomer composition that contains a monomer having a furan ring (hereinafter, also referred to as “furan ring-containing monomer”). Examples of the furan ring-containing monomer include furfuryl alcohol and furfural.

The monomer composition used for synthesizing the furan resin may contain other monomers in addition to the furan ring-containing monomer. Examples of the other monomers include aldehydes, ketones, phenols, and urea. In a case where the monomer composition contains a monomer other than the furan ring-containing monomer, the proportion of the furan ring-containing monomer in the monomer composition is preferably 50% by mole or greater, more preferably 60% by mole or greater, still more preferably 70% by mole or greater, even still more preferably 80% by mole or greater, even still more preferably 90% by mole or greater, and even still more preferably 95% by mole or greater with respect to all monomers contained in the monomer composition.

Specific examples of the furan resin include a furfuryl alcohol single condensate, a furfuryl alcohol-aldehyde co-condensate, a furfural-ketone co-condensate, a furfural-phenol co-condensate, a furfuryl alcohol-urea co-condensate, and a furfuryl alcohol-phenol co-condensate, but the present invention is not limited thereto. Among these, a furfuryl alcohol single condensate or a furfuryl alcohol-furfural co-condensate is preferable as the furan resin.

The furfuryl alcohol single condensate is a resin represented by Formula (A01-1). The furfuryl alcohol-furfural co-condensate is a resin represented by Formula (A01-2).

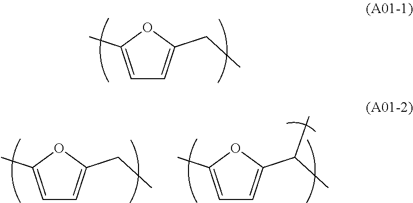

The weight-average molecular weight (Mw) (in terms of polystyrene according to gel permeation chromatography (GPC)) of the component (A01) is not particularly limited, but is preferably in a range of 1,000 to 50,000, more preferably in a range of 2,000 to 30,000, still more preferably in a range of 3,000 to 20,000, and particularly preferably in a range of 5,000 to 20,000.

In a case where the Mw of the component (A01) is less than or equal to the upper limits of the above-described preferable ranges, the solubility in a solvent is satisfactory. In a case where the Mw of the component (A01) is greater than or equal to the lower limits of the above-described preferable ranges, the dry etching resistance is enhanced.

Further, the dispersity (Mw/Mn) of the component (A01) is not particularly limited, but is preferably in a range of 1 to 50, more preferably in a range of 1 to 40, and still more preferably in a range of 1 to 30. Further, Mn denotes the number average molecular weight.

In the composition for forming a resist underlayer film according to the present embodiment, the furan resin (component (A01)) may be used alone or in combination of two or more kinds thereof.

The amount of the component (A01) in the composition for forming a resist underlayer film according to the present embodiment is preferably 50% by mass or greater, more preferably 60% by mass or greater, still more preferably 70% by mass or greater, even still more preferably 80% by mass or greater, and particularly preferably 90% by mass or greater with respect to the mass of the entire resin component contained in the composition for forming a resist underlayer film. The amount of the component (A01) in the composition for forming a resist underlayer film according to the present embodiment may be 100% by mass with respect to the mass of the entire resin component contained in the composition for forming a resist underlayer film.

In a case where the amount of the component (A01) is greater than or equal to the lower limits of the above-described preferable ranges, the antireflection performance and the dry etching resistance of the resist underlayer film are enhanced.

The component (A01) can be produced by performing a polycondensation reaction of a monomer composition containing a furan ring-containing monomer. The polycondensation reaction may be performed in the presence of an acid catalyst or a base catalyst. The reaction temperature is not limited as long as the polycondensation reaction occurs at the temperature, and may be, for example, in a range of 50° C. to 150° C. The reaction time can be set to a time at which the polycondensation reaction sufficiently proceeds, and may be, for example, in a range of 0.5 to 12 hours.

### <<Other Resin Component: Component (A02)>>

The composition for forming a resist underlayer film according to the present embodiment may contain a resin (hereinafter, also referred to as “component (A02)”) other than the component (A01). Examples of the component (A02) include a resin having a constitutional unit with a hydroxystyrene skeleton (for example, polyhydroxystyrene), a novolak resin, and an acrylic resin.

### <Thermal Acid Generator Component: Component (T0)>

The composition for forming a resist underlayer film according to the present embodiment contains a thermal acid generator component (hereinafter, also referred to as “component (T0)”). The thermal acid generator is a compound that generates an acid by being heated. The thermal acid generator is different from a photoacid generator described below, and thus does not generate an acid upon light exposure. The thermal acid generator is, for example, a compound that generates an acid by being heated at 200° C. or lower. Examples of the thermal acid generator component (component (T0)) contained in the composition for forming a resist underlayer film according to the present embodiment include compounds capable of generating an acid by being heated at 60° C. to 200° C.

Examples of the component (T0) include a perfluoroalkyl sulfonate (a trifluoromethane sulfonate, a perfluorobutane sulfonate, or the like), a hexafluorophosphate, a boron trifluoride salt, and a boron trifluoride ether complex compound.

Examples of the component (T0) include a compound represented by General Formula (T0-1) (hereinafter, also referred to as “component (T01)”) and a compound represented by General Formula (T0-2) (hereinafter, also referred to as “component (T02)”).

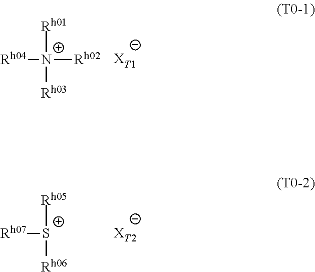

[In Formula (T0-1), R^{h01} to R^{h04} each independently represent a group selected from the group consisting of a hydrogen atom, an aryl group, and an alkyl group having 1 to 20 carbon atoms, and at least one of R^{h01} to R^{h04} represents an aryl group. The aryl group and the alkyl group may have a substituent. X_{T1}_{^{−}} represents a counter anion.

In Formula (T0-2), R^{h05} to R^{h07} each independently represent a group selected from the group consisting of an aryl group and an alkyl group having 1 to 20 carbon atoms, and at least one of R^{h05} to R^{h07} represents an aryl group. The aryl group and the alkyl group may have a substituent. X_{T2}_{^{−}} represents a counter anion.]

### <<Anion Moiety of Component (T01) and Component (T02)>>

Examples of X_{T1}_{^{−}} in Formula (T0-1) and X_{T2}_{^{−}} in Formula (T0-2) include a hexafluorophosphate anion, a perfluoroalkyl sulfonate anion (a trifluoromethane sulfonate anion, and a perfluorobutane sulfonate anion, or the like), a tetrakis(pentafluorophenyl) borate anion.

Among these, a perfluoroalkyl sulfonate anion is preferable, a trifluoromethane sulfonate anion or a perfluorobutane sulfonate anion is more preferable, and a trifluoromethane sulfonate anion is still more preferable.

### <<Cation Moiety of Component (T01)>>

In Formula (T0-1), the alkyl group as R^{h01} to R^{h04} has 1 to 20 carbon atoms, preferably 1 to 10 carbon atoms, more preferably 1 to 5 carbon atoms. Among these, a linear alkyl group having 1 to 5 carbon atoms or a branched alkyl group having 3 to 5 carbon atoms is still more preferable. Specific examples of the alkyl group as R^{h01} to R^{h04} include a methyl group, an ethyl group, a propyl group, an isopropyl group, an n-butyl group, an isobutyl group, a tert-butyl group, a pentyl group, an isopentyl group, and a neopentyl group. Among these, a methyl group or an ethyl group is preferable.

The alkyl group as R^{h01} to R^{h04} may have a substituent. Examples of the substituent include an alkoxy group, a halogen atom, a halogenated alkyl group, a hydroxyl group, a carbonyl group, a nitro group, an amino group, and a cyclic group.

The alkoxy group as the substituent of the alkyl group is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group and an ethoxy group.

Examples of the halogen atom as the substituent of the alkyl group include a fluorine atom, a chlorine atom, a bromine atom, and an iodine atom. Among these, a fluorine atom is preferable.

Examples of the halogenated alkyl group as the substituent of the alkyl group include a group in which some or all hydrogen atoms of the alkyl group having 1 to 5 carbon atoms (such as a methyl group, an ethyl group, a propyl group, an n-butyl group, or a tert-butyl group) have been substituted with the halogen atoms.

The carbonyl group as the substituent of the alkyl group is a group (>C═O) that substitutes a methylene group (—CH₂—) constituting the alkyl group.

Examples of the cyclic group as the substituent of the alkyl group include an aromatic hydrocarbon group and an alicyclic hydrocarbon group (which may be polycyclic or monocyclic). Examples of the aromatic hydrocarbon group here include the same groups as those for the aryl group represented by R^{h01} to R^{h04} described below. In the alicyclic hydrocarbon group here, as the monocyclic alicyclic hydrocarbon group, a group obtained by removing one or more hydrogen atoms from a monocycloalkane is preferable. The monocycloalkane has preferably 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the number of carbon atoms of the polycycloalkane is preferably in a range of 7 to 30. Among these, a polycycloalkane having a crosslinked ring polycyclic skeleton such as adamantane, norbornane, isobornane, tricyclodecane, or tetracyclododecane; and a polycycloalkane having a condensed ring polycyclic skeleton such as a cyclic group having a steroid skeleton are preferable as the polycycloalkane.

In Formula (T0-1), the aryl group for R^{h01} to R^{h04} is a hydrocarbon group having at least one aromatic ring.

The aromatic ring is not particularly limited as long as the aromatic ring is a cyclic conjugated system having (4n+2) π electrons and may be monocyclic or polycyclic. The number of carbon atoms in the aromatic ring is preferably in a range of 5 to 30, more preferably in a range of 5 to 20, still more preferably in a range of 6 to 15, and particularly preferably in a range of 6 to 12.

Specifically, as the aromatic ring, an aromatic hydrocarbon ring such as benzene, naphthalene, anthracene, and phenanthrene; and an aromatic heterocyclic ring in which some carbon atoms constituting the aromatic hydrocarbon ring are substituted with heteroatoms are exemplary examples. Examples of the heteroatom in the aromatic heterocyclic rings include an oxygen atom, a sulfur atom, and a nitrogen atom. Specific examples of the aromatic heterocyclic ring include a pyridine ring and a thiophene ring.

Specific examples of the aryl group as R^{h01} to R^{h04} include a group in which one hydrogen atom has been removed from the aromatic hydrocarbon ring or the aromatic heterocyclic ring; a group in which one hydrogen atom has been removed from an aromatic compound having two or more aromatic rings (for example, biphenyl or fluorene); and a group in which one hydrogen atom of the aromatic hydrocarbon ring or the aromatic heterocyclic ring has been substituted with an alkylene group (for example, an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aromatic hydrocarbon ring or the aromatic heterocyclic ring has preferably 1 to 4 carbon atoms, more preferably 1 or 2 carbon atoms, or particularly preferably 1 carbon atom. Among these, a group obtained by removing one hydrogen atom from the aromatic hydrocarbon ring or aromatic heterocyclic ring, and a group in which one hydrogen atom of the aromatic hydrocarbon ring or aromatic heterocyclic ring is substituted with an alkylene group are preferable, and a group obtained by removing one hydrogen atom from the aromatic hydrocarbon ring and a group in which one hydrogen atom of the aromatic hydrocarbon ring is substituted with an alkylene group are still more preferable.

The aryl group as R^{h01} to R^{h04} may have a substituent. Examples of the substituent include an alkyl group, an alkoxy group, a halogen atom, a halogenated alkyl group, a hydroxyl group, a carbonyl group, a nitro group, an amino group, a cyclic group, and an alkylcarbonyloxy group.

The alkyl group as the substituent of the aryl group is preferably an alkyl group having 1 to 5 carbon atoms and preferably a methyl group, an ethyl group, a propyl group, an n-butyl group, or a tert-butyl group.

The description of the alkoxy group, the halogen atom, the halogenated alkyl group, the carbonyl group, and the cyclic group as the substituent of the aryl group is the same as the description of the alkoxy group, the halogen atom, the halogenated alkyl group, the carbonyl group, and the cyclic group as the substituent of the alkyl group described above.

In the alkylcarbonyloxy group as a substituent of the aryl group, the number of carbon atoms in the alkyl group is preferably in a range of 1 to 5. Specific examples of the alkyl group include a methyl group, an ethyl group, a propyl group, and an isopropyl group. Among these, a methyl group or ethyl group is preferable, and a methyl group is more preferable.

In Formula (T0-1), at least one of R^{h01} to R^{h04} represents an aryl group which may have a substituent.

Specific examples of the cation moiety of the component (T01) are shown below.

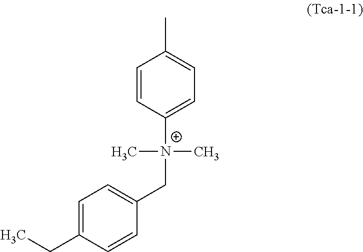 [SMILES: CCc1ccc(C[N+](C)(C)c2ccc(C)cc2)cc1]

### <<Cation Moiety of Component (T02)>>

In Formula (T0-2), the description of the alkyl group and the aryl group as R^{h05} to R^{h07} is the same as the description of the alkyl group and the aryl group as R^{h01} to R^{h04} described above.

In Formula (T0-2), at least one of R^{h05} to R^{h07} represents an aryl group which may have a substituent.

Specific examples of the cation moiety of the component (T02) are shown below.

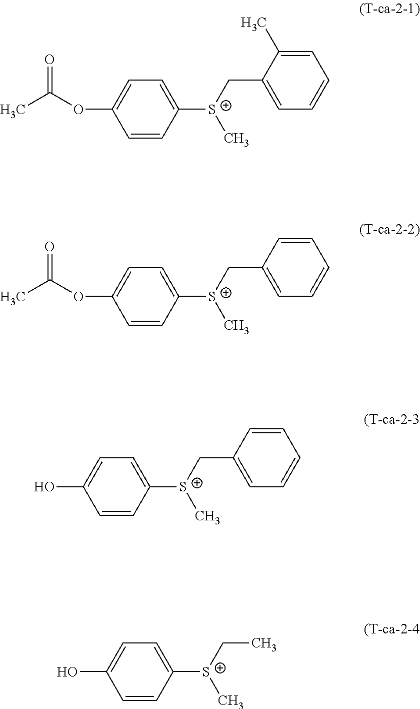 [SMILES: CC(=O)Oc1ccc([S+](C)Cc2ccccc2C)cc1 ; CC(=O)Oc1ccc([S+](C)Cc2ccccc2)cc1 ; C[S+](Cc1ccccc1)c1ccc(O)cc1 ; CC[S+](C)c1ccc(O)cc1]

As the component (T0), a compound which is a quaternary ammonium salt is preferable, and the component (T01) is more preferable. Sulfonic acid is preferable as the acid generated by the decomposition of the component (T0) by heat. Examples of a commercially available product of the component (T01) include TAG-2689 (manufactured by King Industries, Inc.).

The component (T0) may be used alone or in combination of two or more kinds thereof.

The amount of the component (T0) in the composition for forming a resist underlayer film according to the present embodiment is preferably in a range of 0.01 to 20 parts by mass, more preferably in a range of 0.1 to 10 parts by mass, still more preferably in a range of 0.5 to 5 parts by mass, and particularly preferably in a range of 1 to 4 parts by mass with respect to 100 parts by mass of the component (A01).

In a case where the amount of the component (T0) is in the above-described preferable ranges, the curing properties of the resist underlayer film are enhanced.

### <Solvent: Component (S0)>

The composition for forming a resist underlayer film according to the present embodiment contains a solvent (hereinafter, also referred to as “component (S0)”).

The component (S0) is used to dissolve each component contained in the composition for forming a resist underlayer film. The component (S0) is not particularly limited, and a component that has been typically used as a solvent of a composition for forming a resist underlayer film can be used as the component (S0) without particular limitation.

Examples of the component (S0) include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond, such as ethylene glycol monoacetate, diethylene glycol monoacetate, propylene glycol monoacetate, and dipropylene glycol monoacetate; polyhydric alcohol derivatives of compounds having an ether bond such as monoalkyl ether or monophenyl ether, such as monomethylether, monoethylether, monopropylether, or monobutylether of polyhydric alcohols or compounds having an ester bond [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene, and mesitylene; and dimethylsulfoxide (DMSO).

Among these, it is preferable to employ PGME, PGMEA, ethyl lactate, butyl lactate, γ-butyrolactone, cyclohexanone, or two or more kinds of mixed solvents selected from these, and the like from the viewpoint of further improving the leveling property.

The component (S0) may be used alone or in the form of a mixed solvent of two or more kinds thereof.

The amount of the component (S0) to be used is not particularly limited as long as a substrate or the like can be coated with the composition for forming a resist underlayer film at the concentration of the component (S0). The amount of the component (S0) to be used can be appropriately set according to the film thickness of the resist underlayer film to be formed. The component (S0) may be used, for example, such that the solid content concentration of the composition for forming a resist underlayer film (the concentration of the components other than the solvent) is about 2% to 30% by mass. The solid content concentration of the composition for forming a resist underlayer film is preferably in a range of 5% to 20% by mass and more preferably in a range of 10% to 20% by mass.

### <Optional Components>

The composition for forming a resist underlayer film according to the present embodiment may contain optional components in addition to the above-described components. Examples of the optional components include a photoacid generator, a crosslinking agent, a surfactant, a crosslinking acceleration catalyst, a light absorbing agent, a rheology modifier, and an adhesion assistant.

### <<Photoacid Generator Component: Component (B0)>>

The composition for forming a resist underlayer film according to the present embodiment may contain a photoacid generator component (hereinafter, also referred to as “component (B0)”) that generates an acid upon light exposure. The photoacid generator generates an acid in a case where the resist film formed on the resist underlayer film is exposed to light. This acid acts on the resist film in contact with the resist underlayer film, and can assist the action of the acid generated from the photoacid generator contained in the resist film. Therefore, in a case where the composition for forming a resist underlayer film contains a photoacid generator, the rectangularity of the resist pattern can be improved. The photoacid generator typically does not generate an acid in a case of being heated at 200° C. or lower. The photoacid generator used in the composition for forming a resist underlayer film according to the present embodiment is a compound that does not generate an acid at a baking temperature during the formation of the resist underlayer film.

A component that is typically used as a photoacid generator for a resist composition can be used as the component (B0) without particular limitation. Examples of the component (B0) include onium salt-based photoacid generators such as iodonium salts and sulfonium salts; oxime sulfonate-based photoacid generators; diazomethane-based photoacid generators such as bisalkyl or bisaryl sulfonyl diazomethanes and poly(bis-sulfonyl)diazomethanes; nitrobenzyl sulfonate-based photoacid generators; iminosulfonate-based photoacid generators; and disulfone-based photoacid generators.

An onium salt-based photoacid generator is preferable as the component (B0). Examples of the onium salt-based photoacid generator include a compound represented by General Formula (b-1), (b-2), or (b-3).

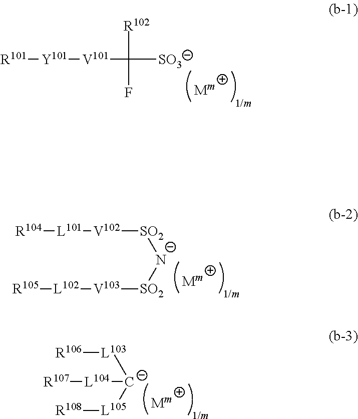

[In the formulae, R¹⁰¹ and R¹⁰⁴ to R¹⁰⁸ each independently represent a cyclic group which may have a substituent, a chain-like alkyl group which may have a substituent, or a chain-like alkenyl group which may have a substituent. R¹⁰⁴ and R¹⁰⁵ may be bonded to each other to form a ring structure. R¹⁰² represents a fluorinated alkyl group having 1 to 5 carbon atoms or a fluorine atom. Y¹⁰¹ represents a divalent linking group having an oxygen atom or a single bond. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO—, or —SO₂—. m represents an integer of 1 or greater, and M^{m+} represents an m-valent onium cation.]

### Anion Moiety

The cyclic group which may have a substituent as R¹⁰¹ and R¹⁰⁴ to R¹⁰⁸ is preferably a cyclic hydrocarbon group, and may be an aromatic hydrocarbon group or an aliphatic hydrocarbon group. The aliphatic hydrocarbon group may be saturated or unsaturated, but is preferably saturated.

The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Examples of the aromatic ring of the aromatic hydrocarbon group include benzene, fluorene, naphthalene, anthracene, phenanthrene, biphenyl, or an aromatic heterocyclic ring in which some carbon atoms constituting any of these aromatic rings have been substituted with heteroatoms. Examples of the heteroatom in the aromatic heterocyclic rings include an oxygen atom, a sulfur atom, and a nitrogen atom.

Examples of the aromatic hydrocarbon group include a group in which one hydrogen atom has been removed from the above-described aromatic ring (an aryl group such as a phenyl group or a naphthyl group) and a group in which one hydrogen atom in the aromatic ring has been substituted with an alkylene group (an arylalkyl group such as a benzyl group, a phenethyl group, a 1-naphthylmethyl group, a 2-naphthylmethyl group, a 1-naphthylethyl group, or a 2-naphthylethyl group). The alkylene group (an alkyl chain in the arylalkyl group) has preferably 1 to 4 carbon atoms, more preferably 1 or 2 carbon atoms, and still preferably 1 carbon atom.

Examples of the cyclic aliphatic hydrocarbon group include an aliphatic hydrocarbon group having a ring in the structure thereof. Examples of the aliphatic hydrocarbon group having a ring in the structure thereof include an alicyclic hydrocarbon group (group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed in the middle of a linear or branched aliphatic hydrocarbon group. The alicyclic hydrocarbon group has preferably 3 to 20 carbon atoms and more preferably 3 to 12 carbon atoms.

The alicyclic hydrocarbon group may be a polycyclic group or a monocyclic group. As the monocyclic alicyclic hydrocarbon group, a group in which one or more hydrogen atoms have been removed from a monocycloalkane is preferable. The monocycloalkane has preferably 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the polycyclic alicyclic hydrocarbon group has preferably 7 to 30 carbon atoms. Examples of the polycycloalkane include a polycycloalkane having a crosslinked ring-based polycyclic skeleton such as adamantane, norbornane, isobornane, tricyclodecane, or tetracyclododecane; and a polycycloalkane having a condensed ring-based polycyclic skeleton such as a cyclic group having a steroid skeleton.

The chain-like alkyl group which may have a substituent as R¹⁰¹ and R¹⁰⁴ to R¹⁰⁸ may be linear or branched. The linear alkyl group has preferably 1 to 20 carbon atoms, more preferably 1 to 15 carbon atoms, and still more preferably 1 to 10 carbon atoms.

The branched alkyl group has preferably 3 to 20 carbon atoms, more preferably 3 to 15 carbon atoms, and still more preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

The chain-like alkenyl group which may have a substituent as R¹⁰¹ and R¹⁰⁴ to R¹⁰⁸ may be linear or branched. The linear alkenyl group has preferably 2 to 10 carbon atoms, more preferably 2 to 5 carbon atoms, still more preferably 2 to 4 carbon atoms, and particularly preferably 3 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Y¹⁰¹ represents a single bond or a divalent linking group having an oxygen atom. In a case where Y¹⁰¹ represents a divalent linking group having an oxygen atom, Y¹⁰¹ may have an atom other than the oxygen atom. Examples of atoms other than an oxygen atom include a carbon atom, a hydrogen atom, a sulfur atom, and a nitrogen atom.

Examples of the divalent linking group having an oxygen atom include non-hydrocarbon-based oxygen atom-containing linking groups such as an oxygen atom (ether bond; —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); and combinations of the non-hydrocarbon-based oxygen atom-containing linking groups with an alkylene group. Further, a sulfonyl group (—SO₂—) may be linked to the combination.

It is preferable that the alkylene group and the fluorinated alkylene group as V¹⁰¹ to V¹⁰³ have 1 to 4 carbon atoms. It is preferable that V¹⁰¹ to V¹⁰³ represent a single bond or a fluorinated alkylene group having 1 to 4 carbon atoms.

R¹⁰² represents a fluorine atom or a fluorinated alkyl group having 1 to 5 carbon atoms. R¹⁰² represents preferably a fluorine atom or a perfluoroalkyl group having 1 to 5 carbon atoms and more preferably a fluorine atom.

### Cation Moiety

M^{m+} represents an m-valent onium cation. A sulfonium cation or an iodonium cation is preferable as the onium cation. m represents an integer of 1 or greater.

Examples of the cation moiety ((M^{m+})_{l/m}) include organic cations each represented by General Formulae (ca-1) to (ca-3).

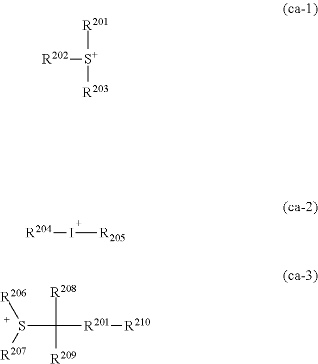

[In the formulae, R²⁰¹ to R²⁰⁷ each independently represent an aryl group, an alkyl group, or an alkenyl group, which may have a substituent. R²⁰¹ to R²⁰³, and R²⁰⁶ and R²⁰⁷ may be bonded to each other to form a ring with the sulfur atoms in the formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or a SO₂-containing cyclic group which may have a substituent. L²⁰¹ represents —C(═O)— or —C(═O)—O—.]

Examples of the aryl group as R²⁰¹ to R²⁰⁷ include an aryl group having 6 to 20 carbon atoms. Among these, a phenyl group or a naphthyl group is preferable.

Examples of the alkyl group as R²⁰¹ to R²⁰⁷ include a chain-like alkyl group having 1 to 30 carbon atoms and a cyclic alkyl group having 3 to 30 carbon atoms.

Examples of the alkenyl group as R²⁰¹ to R²⁰⁷ include an alkenyl group having 2 to 10 carbon atoms.

R²⁰⁸ and R²⁰⁹ each independently represent a hydrogen atom or an alkyl group having 1 to 5 carbon atoms and preferably a hydrogen atom or an alkyl group having 1 to 3 carbon atoms. In a case where R²⁰⁸ and R²⁰⁹ represent an alkyl group, R²⁰⁸ and R²⁰⁹ may be bonded to each other to form a ring.

Examples of the aryl group as R²¹⁰ include an unsubstituted aryl group having 6 to 20 carbon atoms. Among these, a phenyl group or a naphthyl group is preferable.

Examples of the alkyl group as R²¹⁰ include a chain-like alkyl group having 1 to 30 carbon atoms and a cyclic alkyl group having 3 to 30 carbon atoms.

It is preferable that the alkenyl group as R²¹⁰ has 2 to 10 carbon atoms.

As the SO₂-containing cyclic group as R²¹⁰, a —SO₂-containing polycyclic group is preferable, and a sultone-containing polycyclic group is more preferable.

The component (B0) is preferably a compound represented by Formula (b-1) and more preferably contains a cation having a triphenylsulfonium skeleton.

The component (B0) may be used alone or in a combination of two or more kinds thereof.

In a case where the composition for forming a resist underlayer film according to the present embodiment contains the component (B0), the amount of the component (B0) is preferably in a range of 0.01 to 20 parts by mass, more preferably in a range of 0.1 to 10 parts by mass, still more preferably 0.5 to 5 parts by mass, and particularly preferably in a range of 1 to 3 parts by mass with respect to 100 parts by mass of the component (A01). In a case where the amount of the component (B0) is in the above-described preferable ranges, the shape of the resist pattern is likely to be enhanced.

### <<Crosslinking Agent: Component (C0)>>

The composition for forming a resist underlayer film according to the present embodiment may contain a crosslinking agent. Examples of the crosslinking agent include an amino-based crosslinking agent such as glycoluril having a methylol group or an alkoxymethyl group; and a melamine-based crosslinking agent. Specific examples of the crosslinking agent include Nikalac [registered trademark] series (Nikalac MX270 and the like) manufactured by Sanwa Chemical Co., Ltd.

The crosslinking agent may be used alone or in combination of two or more kinds thereof.

In a case where the composition for forming a resist underlayer film according to the present embodiment contains a crosslinking agent, the amount of the crosslinking agent is preferably in a range of 1 to 50 parts by mass, more preferably in a range of 1 to 40 parts by mass, and still more preferably in a range of 1 to 30 parts by mass with respect to 100 parts by mass of the component (A01).

Since the crosslinking properties of the component (A01) are enhanced, the composition for forming a resist underlayer film according to the present embodiment may contain no crosslinking agent.

### <<Crosslinking Acceleration Catalyst>>

Examples of the crosslinking acceleration catalyst include acidic compounds such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, and naphthalenecarboxylic acid.

The crosslinking acceleration catalyst may be used alone or in combination of two or more kinds thereof.

### <<Surfactant>

The composition for forming a resist underlayer film according to the present embodiment may contain a surfactant.

Examples of the surfactant include a nonionic surfactant encompassing: polyoxyethylene alkyl ethers such as polyoxyethylene lauryl ether, polyoxyethylene stearyl ether, polyoxyethylene cetyl ether, polyoxyethylene oleyl ether or the like; polyoxyethylene alkyl allyl ethers such as polyoxyethylene octyl phenol ether, polyoxyethylene nonyl phenol ether or the like; polyoxyethylene-polyoxypropylene block copolymers; sorbitan fatty acid esters such as sorbitan monolaurate, sorbitan monopalmitate, sorbitan monostearate, sorbitan monooleate, sorbitan trioleate, sorbitan tristearate or the like; polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate or the like; fluorinated surfactants such as F-top [registered trademark] EF 301, EF 303, and EF 352 [collectively manufactured by Mitsubishi Materials Electronic Chemicals Co., Ltd. (formerly Tochem Products), trade names], Megafac [registered trademark] F171, F173, R-30, and R-40 [collectively manufactured by DIC Corporation (formerly Dai Nippon Ink Co., Ltd.), trade names], Fluorad FC430 and FC431 (collectively manufactured by Sumitomo 3M Co., Ltd., trade names), Asahi Guard [registered trademark] AG710, Surflon [registered trademark] S-382, SC101, SC102, SC103, SC104, SC105, and SC106 (collectively manufactured by Asahi Glass Co., Ltd., trade names), or the like; and Organosiloxane Polymer KP341 (manufactured by Shin-Etsu Chemical Co., Ltd.).

The surfactant may be used alone or in combination of two or more kinds thereof.

In a case where the composition for forming a resist underlayer film according to the present embodiment contains a surfactant, the amount of the surfactant is preferably in a range of 0.01 to 20 parts by mass, more preferably in a range of 0.05 to 5 parts by mass, and still more preferably in a range of 0.08 to 1 part by mass with respect to 100 parts by mass of the component (A01).

### <<Light Absorbing Agent>>

The composition for forming a resist underlayer film according to the present embodiment may contain a light absorbing agent.

Examples of the light absorbing agent include commercially available light absorbing agents described in “Technology and Market for Industrial Dyes” (published by CMC) and “Dyes Handbook” (edited by the Society of Synthetic Organic Chemistry), for example, C.I. Disperse Yellow 1, 3, 4, 5, 7, 8, 13, 23, 31, 49, 50, 51, 54, 60, 64, 66, 68, 79, 82, 88, 90, 93, 102, 114, and 124; C.I. Disperse Orange 1, 5, 13, 25, 29, 30, 31, 44, 57, 72, and 73; C.I. Disperse Red 1, 5, 7, 13, 17, 19, 43, 50, 54, 58, 65, 72, 73, 88, 117, 137, 143, 199, and 210; C.I. Disperse Violet 43; C.I. Disperse Blue 96; C.I. Fluorescent Brightening Agent 112, 135, and 163; C.I. Solvent Orange 2 and 45; C.I. Solvent Red 1, 3, 8, 23, 24, 25, 27, and 49; C.I. Pigment Green 10; and C.I. Pigment Brown 2.

The light absorbing agent may be used alone or in combination of two or more kinds thereof.

In a case where the composition for forming a resist underlayer film according to the present embodiment contains a light absorbing agent, the amount of the light absorbing agent is preferably 10 parts by mass or less and more preferably 5 parts by mass or less with respect to 100 parts by mass of the component (A01).

### <<Rheology Modifier>>

The composition for forming a resist underlayer film according to the present embodiment may contain a rheology modifier.

Examples of the rheology modifier include phthalic acid derivatives such as dimethyl phthalate, diethyl phthalate, diisobutyl phthalate, dihexyl phthalate, butyl isodecyl phthalate, or the like; adipic acid derivatives such as dinormal butyl adipate, diisobutyl adipate, diisooctyl adipate, octyl decyl adipate, or the like; maleic acid derivatives such as dinormal butyl malate, diethyl malate, dinonyl malate, or the like; oleic acid derivatives such as methyl oleate, butyl oleate, tetrahydrofurfuryl oleate, or the like; and stearic acid derivatives such as normal butyl stearate, glyceryl stearate, or the like.

The rheology modifier may be used alone or in combination of two or more kinds thereof.

In a case where the composition for forming a resist underlayer film according to the present embodiment contains a rheology modifier, the amount of the rheology modifier is preferably less than 30 parts by mass with respect to 100 parts by mass of the component (A01).

### <<Adhesion Assistant>>

The composition for forming a resist underlayer film according to the present embodiment may contain an adhesion assistant.

Examples of the adhesion assistant include chlorosilanes such as m-trimethylchlorosilane, dimethylvinylchlorosilane, methyldiphenylchlorosilane, chloromethyldimethylchlorosilane, or the like; alkoxysilanes such as trimethylmethoxysilane, dimethyldiethoxysilane, methyldimethoxysilane, dimethylvinylethoxysilane, diphenyldimethoxysilane, phenyltriethoxysilane, or the like; silazanes such as hexamethyldisilazane, N,N′-bis(trimethylsilyl) urea, dimethyltrimethylsilylamine, trimethylsilylimidazole, or the like; silanes such as vinyltrichlorosilane, γ-chloropropyltrimethoxysilane, γ-aminopropyltriethoxysilane, γ-glycidoxypropyltrimethoxysilane, or the like; heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, mercaptopyrimidine, or the like; urea such as 1,1-dimethylurea, 1,3-dimethylurea, or the like; and thiourea compounds.

The adhesion assistant may be used alone or in combination of two or more kinds thereof.

In a case where the composition for forming a resist underlayer film according to the present embodiment contains an adhesion assistant, the amount of the adhesion assistant is preferably less than 5 parts by mass and more preferably less than 2 parts by mass with respect to 100 parts by mass of the component (A01).

The composition for forming a resist underlayer film according to the present embodiment contains a furan resin as a resin component, and contains a thermal acid generator. In this manner, in the resist underlayer film formed by using the composition for forming a resist underlayer film according to the present embodiment, reflection at the interface between the resist underlayer film and the resist film is suppressed. Therefore, a resist pattern having excellent fine resolution, a satisfactory shape, and reduced roughness can be formed. In addition, the resist underlayer film formed of the composition for forming a resist underlayer film according to the present embodiment has excellent etching resistance. Accordingly, the resist underlayer film can be used as a mask during the processing of a substrate by dry etching. Since the resist underlayer film formed of the composition for forming a resist underlayer film according to the present embodiment has both an antireflective film function and a function as a mask during dry etching, it is not necessary to form two layers, that is, the antireflective film and the mask. Therefore, the steps can be simplified.

### (Resist Pattern Formation Method)

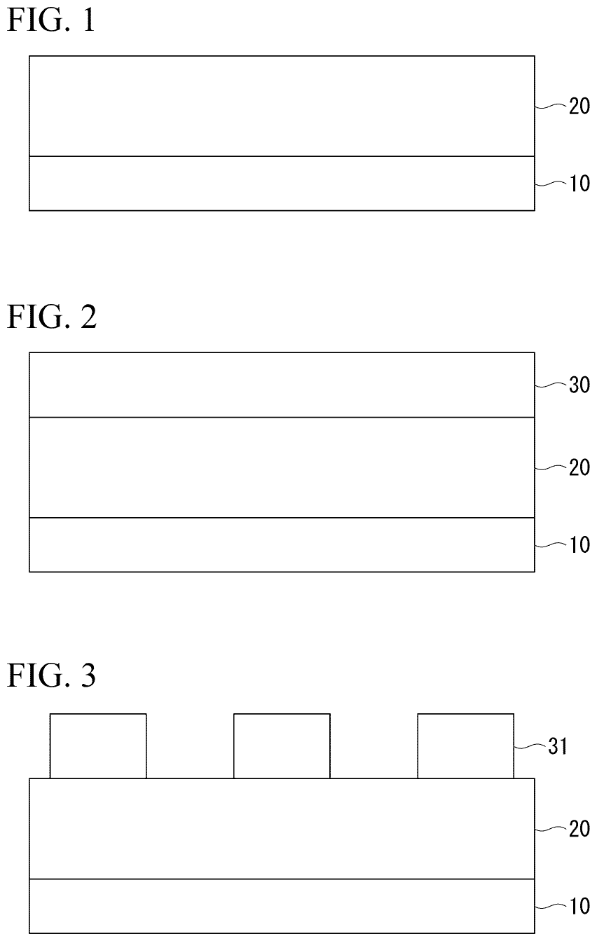

A second aspect of the present invention relates to a resist pattern formation method. The method according to the present embodiment includes a step of forming a resist underlayer film on a substrate using the composition for forming a resist underlayer film according to the first aspect (hereinafter, also referred to as “step (i)”; FIG. 1), a step of forming a resist film on the resist underlayer film using a resist composition (hereinafter, also referred to as “step (ii)”; FIG. 2), a step of exposing the resist film to light (hereinafter, also referred to as “step (iii)”), and a step of developing the resist film exposed to light to form a resist pattern (hereinafter, also referred to as “step (iv)”; FIG. 3).

### <Step (i); FIG. 1>

A substrate 10 is not particularly limited, and a known substrate of the related art can be used. Examples of the substrate 10 include a substrate for an electronic component and a substrate on which a predetermined wiring pattern is formed. Specific examples thereof include a substrate made of a metal such as a silicon wafer, copper, chromium, iron, or aluminum, and a glass substrate. As the materials of the wiring pattern, copper, aluminum, nickel, or gold can be used.

The composition for forming a resist underlayer film according to the first aspect is used for formation of a resist underlayer film 20. Specifically, the substrate 10 is coated with the composition for forming a resist underlayer film according to the first aspect using a spin coating method or the like. Next, the composition is baked and cured to form the resist underlayer film 20. A temperature at which a thermal acid generator component is decomposed to generate an acid can be typically used as the baking temperature. The baking temperature is, for example, in a range of 80° C. to 300° C., preferably in a range of 100° C. to 250° C., and more preferably in a range of 150° C. to 200° C. In a case where the composition for forming a resist underlayer film contains a crosslinking agent, the reaction using a crosslinking agent may be promoted at a temperature of 200° C. or higher. In a case where the composition for forming a resist underlayer film contains a photoacid generator, it is preferable that the baking temperature may be set to a temperature at which the photoacid generator is not decomposed (for example, 300° C. or lower, 250° C. or lower, or 200° C. or lower). The baking time may be set to a time that is sufficient to cure the composition for forming a resist underlayer film. The baking time is, for example, in a range of 10 to 600 seconds, preferably in a range of 30 to 300 seconds, more preferably in a range of 50 to 200 seconds, and still more preferably in a range of 50 to 150 seconds.

The film thickness of the resist underlayer film 20 is not particularly limited and can be appropriately set. The film thickness of the resist underlayer film 20 is, for example, in a range of 50 to 2,000 nm, preferably in a range of 100 to 1,000, more preferably in a range of 150 to 800 nm, and still more preferably in a range of 200 to 500 nm.

<Step (ii); FIG. 2>

A resist composition (photoresist) is used for forming a resist film 30.

The resist composition is not particularly limited as long as a resist pattern can be formed upon light exposure, and a known composition can be used depending on the required performance. Examples of the resist composition include a resist composition containing an alkali-soluble resin, a crosslinking agent that causes a crosslinking reaction by an acid, and a photoacid generator; a resist composition containing a resin that is decomposed by an acid to increase an alkali dissolution rate and a photoacid generator; and a resist composition containing a resin that is decomposed by an acid to decrease an organic solvent dissolution rate and a photoacid generator.

A composition containing silicon (hereinafter, also referred to as “Si-containing resist composition”) may also be used as the resist composition. In a case of forming a pattern by a resist two-layer process, the etching rate of the Si-containing resist film due to oxygen gas is decreased further than the etching rate of the resist underlayer film. Therefore, the resist underlayer film can be etched using the Si-containing resist film as a mask. Examples of the Si-containing resist composition include a composition containing a silicon-containing resin (for example, organopolysiloxane or a derivative thereof), a photoacid generator, and an organic solvent. The Si-containing resist composition may contain an acid diffusion control agent component (such as a photodecomposable base), a fluorine-containing resin, an organic acid, and the like, as necessary.

The resist film 30 can be formed by a known method. For example, the resist underlayer film 20 can be formed by coating the resist underlayer film 20 with the resist composition using a spin coating method or the like and sintering the composition.

The film thickness of the resist underlayer film 20 is, for example, in a range of 10 to 1,000 nm, preferably in a range of 30 to 500 nm, and more preferably in a range of 50 to 200 nm.

<Step (iii)>

The resist film 30 can be exposed to light by irradiation with light or electron beams. For example, the resist film 30 is exposed to light through a predetermined mask. The exposure can be performed by using near ultraviolet rays, far ultraviolet rays, extreme ultraviolet rays (for example, EUV (wavelength of 13.5 nm)), or the like. Specifically, a KrF excimer laser (wavelength of 248 nm), an ArF excimer laser (wavelength of 193 nm), an F2 excimer laser (wavelength of 157 nm), and the like can be used. Among these, an ArF excimer laser (wavelength of 193 nm) or EUV (wavelength of 13.5 nm) is preferable. After the light exposure, post exposure bake (PEB) may be performed as necessary. The heating temperature for PEB is, for example, in a range of 70° C. to 150° C., and the heating time for PEB is, for example, in a range of 0.3 to 10 minutes.

<Step (iv); FIG. 3>

A resist pattern 31 can be formed by developing the resist film 30 exposed to light with a developing solution. For example, in a case where a positive-tone resist composition is used, exposed portions of the resist film are removed to form a resist pattern. In a case where a negative-tone resist composition is used, exposed portions of the resist film are removed to form a resist pattern. Examples of the developing solution include an aqueous solution of quaternary ammonium hydroxide such as tetramethylammonium hydroxide or tetraethylammonium hydroxide; and an organic solvent such as normal butyl acetate, propylene glycol 1-monomethyl ether, or propylene glycol 1-monomethyl ether 2-acetate. The developing solution may contain an additive such as a surfactant. The developing temperature is, for example, in a range of 5° C. to 50° C. The developing time is, for example, in a range of 10 to 600 seconds.

In the resist pattern formation method according to the present embodiment, since the resist underlayer film is formed using the composition for forming a resist underlayer film according to the first aspect, reflection during light exposure is suppressed. Therefore, a resist pattern having high rectangularity and suppressed roughness can be formed with high resolution.

### (Formation Method for Resist Underlayer Film Pattern)

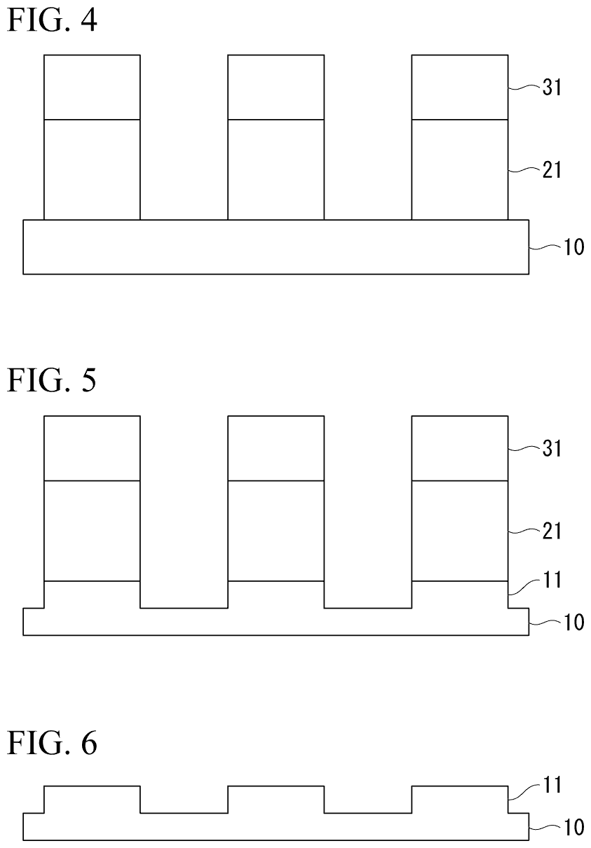

A third aspect of the present invention relates to a formation method for a resist underlayer film pattern. The method according to the present embodiment includes a step of forming a resist pattern by the resist pattern formation method according to the second aspect (hereinafter, also referred to as “step (v)”; FIGS. 1 to 3) and a step of etching the resist underlayer film using the resist pattern as a mask to form a resist underlayer film pattern (hereinafter, also referred to as “step (vi)”; FIG. 4).

### <Step (v); FIGS. 1 to 3>

The resist pattern 31 can be formed by the resist pattern formation method according to the second aspect.

<Step (vi); FIG. 4>

The resist underlayer film 20 can be etched by, for example, oxygen plasma etching. The resist pattern 31 can be transferred to the resist underlayer film 20 to form the resist underlayer film pattern 21 by etching the resist underlayer film 20 using the resist pattern 31 as a mask.

### (Pattern Formation Method)

A fourth aspect of the present invention relates to a pattern formation method. The method according to the present embodiment includes a step of forming a resist underlayer film pattern by the formation method for a resist underlayer film pattern according to the third aspect (hereinafter, also referred to as “step (vii)”; FIG. 4) and a step of etching the substrate using the resist pattern and the resist underlayer film pattern as a mask to form a pattern (hereinafter, also referred to as “step (viii)”; FIGS. 5 and 6).

<Step (vii); FIG. 4>

The resist pattern 31 can be formed by the formation method for a resist underlayer film pattern according to the third aspect.

<Step (viii); FIGS. 5 and 6>

The substrate 10 can be etched by, for example, dry etching using a halogen-based gas (for example, CF₄). The resist underlayer film pattern 21 can be transferred to the substrate 10 to form a pattern 11 by etching the substrate 10 using the resist underlayer film pattern 21 as a mask. Subsequently, the substrate 10 on which the pattern 11 has been formed can be obtained by removing the resist pattern 31 and the resist underlayer film pattern 21.

In the method according to the present embodiment, since the resist underlayer film is formed using the composition for forming a resist underlayer film according to the first aspect, the dry etching resistance of the resist underlayer film is high. Accordingly, the resist underlayer film pattern can be used as a mask during dry etching of the substrate.

In the method according to the present embodiment, since the resist underlayer film has the functions of both the antireflective film and the mask, it is not necessary to separately form the antireflective film. Therefore, labor such as forming the antireflective film and etching the antireflective film is no longer required, and thus the steps can be simplified.

It is preferable that various materials (for example, a resist solvent, a developing solution, a rinse solution, a composition for forming an antireflective film, and a composition for forming a top coat) that are used in the resist composition, the composition for forming a resist underlayer film, and the pattern formation method according to the embodiments described above do not contain impurities such as a metal, a metal salt containing halogen, an acid, an alkali, and a component containing a sulfur atom or a phosphorus atom. Here, examples of the impurities containing metal atoms include Na, K, Ca, Fe, Cu, Mn, Mg, Al, Cr, Ni, Zn, Ag, Sn, Pb, Li, and salts thereof. The amount of the impurities contained in these materials is preferably 200 ppb or less, more preferably 1 ppb or less, still more preferably 100 parts per trillion (ppt) or less, particularly preferably 10 ppt or less, and most preferably substantially zero (less than or equal to the detection limit of the measuring device).

### EXAMPLES

Hereinafter, the present invention will be described in more detail based on examples, but the present invention is not limited to these examples.

### Synthesis Example of Furan Resin (A01)

### Synthesis Example of Furan Resin (A01-1)

0.2 g of a 10 mass % para-toluenesulfonic acid aqueous solution was added to 30 g of furfuryl alcohol, and the mixture was heated at 80° C. for 3 hours. Thereafter, the mixture was cooled to room temperature, and 0.1 g of 2,6-lutidine was added thereto to stop the reaction. The solution after the reaction was added dropwise to 3,000 g of a mixed solution of methanol and water at a mixing ratio of 1:1, the solution was stirred for 30 minutes, and the precipitated furan resin (A01-1) was collected by filtration. Thereafter, the obtained furan resin (A01-1) was washed three times with 1,000 g of a mixed solution of methanol and water at a mixing ratio of 1:1. 2,000 g of propylene glycol 1-monomethyl ether 2-acetate (PGMEA) was added to and dissolved in the washed furan resin (A01-1), and the solution was filtered through 5 A filter paper to remove foreign substances. Thereafter, the resultant was concentrated with a rotary evaporator until the solid content concentration thereof reached 40% by mass. Thereafter, PGMEA was added thereto to adjust the concentration, thereby obtaining a 20 mass % PGMEA solution of the furan resin (A01-1). The weight-average molecular weight (Mw) of the obtained furan resin (A01-1) in terms of standard polystyrene determined by GPC measurement was 9,000, and the polydispersity (Mw/Mn) thereof was 8.9.

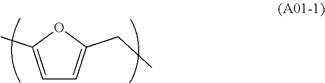

### Synthesis Example of Furan Resin (A01-2)

20 g of furfuryl alcohol and 10 g of furfural were mixed, 0.2 g of a 10 mass % para-toluenesulfonic acid aqueous solution was added thereto, and the mixture was heated at 90° C. for 3 hours. Thereafter, the mixture was cooled to room temperature, and 0.1 g of 2,6-lutidine was added thereto to stop the reaction. The solution after the reaction was added dropwise to 3,000 g of a mixed solution of methanol and water at a mixing ratio of 1:1, the solution was stirred for 30 minutes, and the precipitated furan resin (A01-2) was collected by filtration. Thereafter, the obtained furan resin (A01-2) was washed three times with 1,000 g of a mixed solution of methanol and water at a mixing ratio of 1:1. 2,000 g of PGMEA was added to and dissolved in the washed furan resin (A01-2), and the solution was filtered through 5 A filter paper to remove foreign substances. Thereafter, the resultant was concentrated with a rotary evaporator until the solid content concentration thereof reached 40% by mass. Thereafter, PGMEA was added thereto to adjust the concentration, thereby obtaining a 20 mass % PGMEA solution of the furan resin (A01-2). The weight-average molecular weight (Mw) of the obtained furan resin (A01-2) in terms of standard polystyrene determined by GPC measurement was 19,000, and the polydispersity (Mw/Mn) thereof was 22.9.

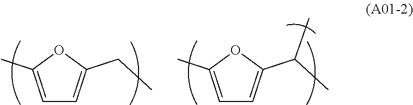

### Preparation of Composition for Forming Resist Underlayer Film

### Examples 1 to 8 and Comparative Examples 1 to 8

Each component listed in Table 1 was blended to prepare a composition for forming a resist underlayer film of each example.

TABLE 1

| | Component | Component | Component | Component | Component |
|---|---|---|---|---|---|
| | (A0) | (T0) | (B0) | (C0) | (S0) |
| Example 1 | (A01)-1 | (T0)-1 | — | — | (S0)-1 |
| | [100] | [3] | | | [800] |
| Example 2 | (A01)-1 | (T0)-1 | (B0)-1 | — | (S0)-1 |
| | [100] | [3] | [1] | | [800] |
| Example 3 | (A01)-1 | (T0)-1 | (B0)-1 | — | (S0)-1 |
| | [100] | [3] | [3] | | [800] |
| Example 4 | (A01)-2 | (T0)-1 | — | — | (S0)-1 |
| | [100] | [2] | | | [850] |
| Example 5 | (A01)-2 | (T0)-1 | — | — | (S0)-1 |
| | [100] | [3] | | | [850] |
| Example 6 | (A01)-2 | (T0)-1 | — | — | (S0)-1 |
| | [100] | [5] | | | [850] |
| Example 7 | (A01)-2 | (T0)-1 | (B0)-1 | — | (S0)-1 |
| | [100] | [3] | [1] | | [850] |
| Example 8 | (A01)-2 | (T0)-1 | (B0)-1 | — | (S0)-1 |
| | [100] | [3] | [3] | | [850] |
| Comparative | (A02)-1 | (T0)-1 | — | — | (S0)-1 |
| Example 1 | [100] | [3] | | | [950] |
| Comparative | (A02)-1 | (T0)-1 | — | (C0)-1 | (S0)-1 |
| Example 2 | [100] | [3] | | [10] | [950] |
| Comparative | (A02)-1 | (T0)-1 | (B0)-1 | (C0)-1 | (S0)-1 |
| Example 3 | [100] | [3] | [1] | [10] | [950] |
| Comparative | (A02)-2 | (T0)-1 | — | — | (S0)-1 |
| Example 4 | [100] | [3] | | | [950] |
| Comparative | (A02)-2 | (T0)-1 | — | (C0)-1 | (S0)-1 |
| Example 5 | [100] | [3] | | [10] | [950] |
| Comparative | (A02)-2 | (T0)-1 | (B0)-1 | (C0)-1 | (S0)-1 |
| Example 6 | [100] | [3] | [1] | [10] | [950] |
| Comparative | (A02)-3 | (T0)-1 | — | — | (S0)-1 |
| Example 7 | [100] | [3] | | | [850] |
| Comparative | (A02)-3 | (T0)-1 | (B0)-1 | — | (S0)-1 |
| Example 8 | [100] | [3] | [1] | | [850] |

In Table 1, each abbreviation has the following meaning. The numerical values in the brackets denote the content in units of parts by mass.
(A01)-1: furan resin (A01-1) shown above
(A01)-2: furan resin (A01-2) shown above
(A02)-1: polyhydroxystyrene (A02-1) shown below
The weight-average molecular weight (Mw) in terms of standard polystyrene determined by GPC measurement was 14,000 and the polydispersity (Mw/Mn) thereof was 1.2.
(A02)-2: novolak resin (A02-2) shown below The weight-average molecular weight (Mw) in terms of standard polystyrene determined by GPC measurement was 33,000 and the polydispersity (Mw/Mn) thereof was 16.8.
(A02)-3: methacrylic resin (A02-3) shown below The weight-average molecular weight (Mw) in terms of standard polystyrene determined by GPC measurement was 9,700 and the polydispersity (Mw/Mn) thereof was 2.5. The copolymer composition ratio (l/m) (the proportion (molar ratio) between constitutional units in the structural formula) acquired by ¹³C-NMR was 50/50.

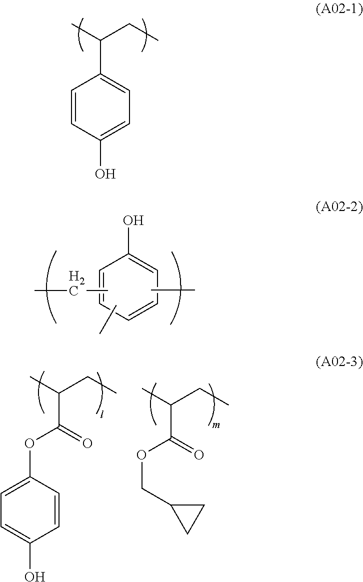

(T0)-1: K-PURE (registered trademark) TAG-2689 (manufactured by King Industries, Inc.). The component is a quaternary ammonium salt of trifluoromethanesulfonic acid.
(B0)-1: photoacid generator consisting of compound (B0-1) shown below
(C0)-1: crosslinking agent consisting of compound (C0-1) shown below

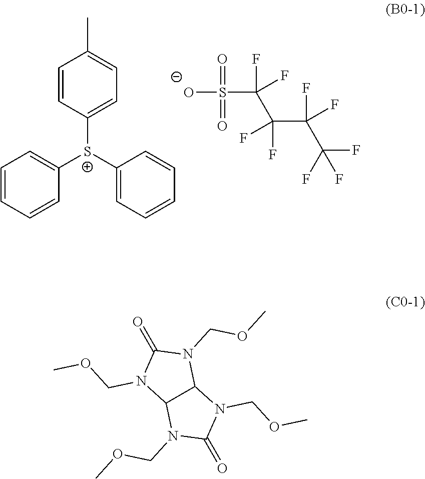

(S0)-1: propylene glycol 1 monomethyl ether 2-acetate (PGMEA)

### <Formation of Resist Underlayer Film>

A 12-inch silicon wafer was coated with the composition for forming a resist underlayer film of each example using a spin coater. The composition was baked on a hot plate at 160° C. in Examples 1 to 8, at 240° C. in Comparative Examples 1 to 6, and at 180° C. in Comparative Examples 7 and 8, for 90 seconds to form a resist underlayer film having a film thickness of 300 nm. In Comparative Examples 1 to 6, the crosslinking reaction of the component (A0) (resin component) was promoted at a high baking temperature.

### <Formation of Resist Pattern>

### <<Preparation of Resist Composition>>

Each component listed in Table 2 was blended to prepare a resist composition.

TABLE 2

| | Component | Component | Component | Component | Component | Component |
|---|---|---|---|---|---|---|
| | (A) | (B) | (D) | (E) | (F) | (S) |
| Resist | (A)-1 | (B)-1 | (D)-1 | (E)-1 | (F)-1 | (S)-1 |
| composition 1 | [100] | [5] | [5] | [1.5] | [3] | [2400] |
| Resist | (A)-2 | (B)-1 | (D)-1 | (E)-1 | (F)-1 | (S)-1 |
| composition 2 | [100] | [5] | [5] | [1.5] | [3] | [2400] |

In Table 2, each abbreviation has the following meaning. The numerical values in the brackets denote the content in units of parts by mass.
(A)-1: polymer compound represented by Formula (A-1) The weight-average molecular weight (Mw) in terms of standard polystyrene determined by GPC measurement was 6,900, and the polydispersity (Mw/Mn) thereof was 2.5. The copolymer composition ratio (l/m/n) (the ratio (molar ratio) between constitutional units in the structural formula) determined by ¹³C-NMR was 40/30/30.
(A)-2: polymer compound represented by Formula (A-2) The weight-average molecular weight (Mw) in terms of standard polystyrene determined by GPC measurement was 5,500, and the polydispersity (Mw/Mn) thereof was 1.6. The copolymer composition ratio (l/m) (the proportion (molar ratio) between constitutional units in the structural formula) acquired by ¹³C-NMR was 50/50.

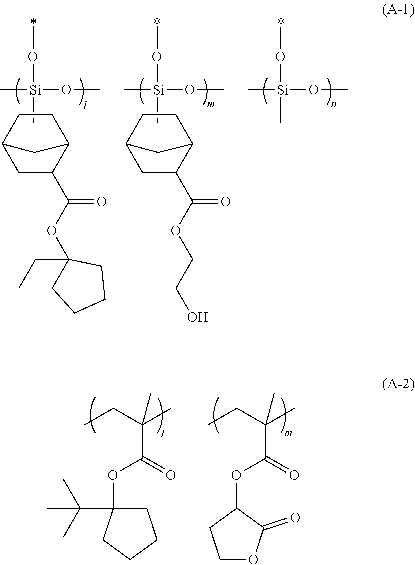

(B)-1: acid generator consisting of compound represented by Formula (B-1)
(D)-1: acid diffusion control agent consisting of compound represented by Formula (D-1)

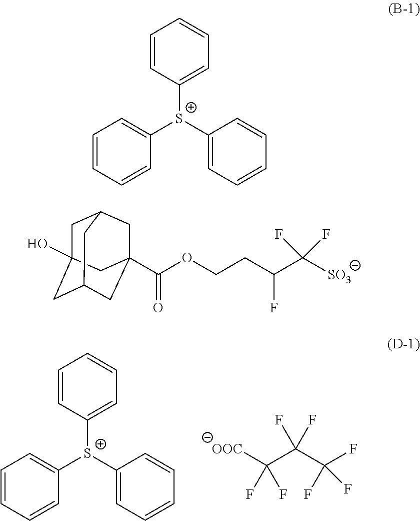

(E)-1: salicylic acid
(F)-1: polymer compound represented by Formula (F-1) The weight-average molecular weight (Mw) in terms of standard polystyrene determined by GPC measurement was 26,000, and the polydispersity (Mw/Mn) thereof was 1.5. The copolymer composition ratio (the ratio (the molar ratio) among constitutional units in the structural formula) determined by ¹³C-NMR is l/m=80/20.

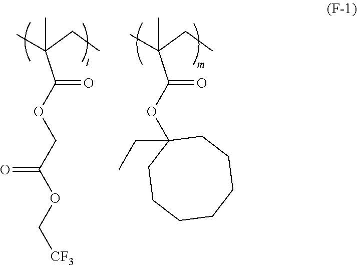

(S)-1: mixed solvent of propylene glycol 1-monomethyl ether (PGME), propylene glycol 1-monomethyl ether 2-acetate (PGMEA) at a mass ratio of 1:5

### <<Resist Pattern Formation 1: Resist Composition |>>

### Examples 1 to 8 and Comparative Examples 1 to 8

The resist underlayer film of each example formed in the section of <formation of resist underlayer film> above was coated with a resist composition 1 using a spin coater. Next, the composition was subjected to a post applied bake (PAB) treatment on a hot plate at 100° C. for 60 seconds and dried, thereby forming a resist film with a film thickness of 95 nm.

Next, the resist film was selectively irradiated with an ArF excimer laser (193 nm) through a photomask (halftone: 6%) using an ArF exposure apparatus for liquid immersion XT 1900Gi [manufactured by ASML; numerical aperture (NA)=1.35, Dipole 35X, Sigma (0.78/0.97), Y deflection, liquid immersion medium: ultrapure water]. Thereafter, a PEB treatment was carried out at 100° C. for 60 seconds.

Next, alkali development was carried out with a 2.38 mass % TMAH aqueous solution (trade name: NMD-3, manufactured by Tokyo Ohka Kogyo Co., Ltd.) at 23° C. for 20 seconds, and water rinsing was carried out using pure water for 15 seconds, followed by shake-off drying. In this manner, a 1:1 line and space (LS) pattern having a line width of 40 nm was formed.

### <<Formation 2 of Resist Pattern: Resist Composition 2>>

### Example 7-2

The resist underlayer film of Example 7 which had been formed in the section of <formation of resist underlayer film> above was coated with a resist composition 2 using a spin coater. Next, the composition was subjected to a post applied bake (PAB) treatment on a hot plate at 90° C. for 60 seconds and dried, thereby forming a resist film with a film thickness of 95 nm. Thereafter, a 1:1 line and space (LS) pattern with a line width of 40 nm was formed by the same method as in the section of <<formation 1 of resist pattern: resist composition 1>> except that the temperature in the PEB treatment was set to 90° C.

### [Measurement of Optical Constant]

The refractive index and the extinction coefficient at a wavelength of 193 nm were measured for the resist underlayer film of each example which had been formed in the section of <formation of resist underlayer film> above using spectroscopic ellipsometry VUV-M2000 (manufactured by J. A. Woollam). The reflectivity at the interface between the resist underlayer film and the resist film was calculated from the obtained refractive index and the obtained extinction coefficient, and the refractive index and the extinction coefficient of the resist film to be formed. The obtained results are listed in the columns of “refractive index (193 nm)”, “extinction coefficient (193 nm)”, and “reflectivity” in Table 3.

### [Etching Resistance]

The resist underlayer film of each example which had been formed in the section of <formation of resist underlayer film> above was treated for 90 seconds using a TCP type dry etching device and subjected to dry etching (etching gas CF₄/N₂=80 sccm/100 sccm, pressure: 10 Pa, RF output: 600 W). The film thickness was measured before and after the dry etching performed using the etching gas, and the etching rate was calculated from a change in the film thickness. The obtained results are listed in the columns of “etching rate (nm/s)” in Table 3.

### [Evaluation of Optimum Exposure Amount (Eop)]

An optimum exposure amount Eop (mJ/cm²) for forming the LS pattern having the target size was determined as described in the section of <Formation of resist pattern>. The results are listed in the columns of “Eop (mJ/cm²)” in Table 4.

### [Evaluation of Resist Pattern Shape]

The cross-sectional shape of the LS pattern which had been formed in the section of <formation of resist pattern> above was observed using a CD-SEM (scanning electron microscope, acceleration voltage: 10 kV, trade name: SU-8000, manufactured by Hitachi High-Tech Corporation). The results of evaluating the cross-sectional shape of the LS pattern according to the following evaluation criteria are listed in the columns of “pattern shape” in Table 4.

### Evaluation Criteria

S: The cross-sectional shape was a rectangular shape.
A: The cross-sectional shape was a rectangular shape, but trailings were observed at the bottom of the pattern.
B: The cross-sectional shape was not a rectangular shape.

### [Evaluation of Linewise Roughness (LWR)]

The triple value (3σ) (unit: nm) of the standard deviation (σ) determined from the measurement results was calculated by measuring 400 line positions in the longitudinal direction of the line with a scanning electron microscope (acceleration voltage: 800 V, trade name: S-9380, manufactured by Hitachi High-Tech Corporation). The results are listed in the columns of “LWR” in Table 4.

In a case where the value of the 30 decreases, this indicates that the roughness of a line side wall decreases and an LS pattern with a uniform width can be obtained.

### [Evaluation of Line Edge Roughness (LER)]

The line edge width (the width of variation from the reference straight line) was measured at 100 sites using a scanning electron microscope (acceleration voltage: 800V, trade name: S-9380, manufactured by Hitachi High-Tech Corporation). Next, the triple value (3σ) (unit: nm) of the standard deviation (σ) determined from the measurement results was calculated. The results are listed in the columns of “LER” in Table 4.

In a case where the value of the 30 σ decreases, this indicates that the roughness of a line side wall decreases and an LS pattern with a uniform width can be obtained.

TABLE 3

| | Refractive | Extinction | | |
|---|---|---|---|---|
| | index | coefficient | | Etching rate |
| | (193 nm) | (193 nm) | Reflectivity | (nm/s) |
| Example 1 | 1.63 | 0.22 | 0.2% | 0.98 |
| Example 2 | 1.62 | 0.22 | 0.2% | 0.97 |
| Example 3 | 1.62 | 0.23 | 0.2% | 1.00 |
| Example 4 | 1.62 | 0.22 | 0.2% | 0.98 |
| Example 5 | 1.62 | 0.22 | 0.2% | 1.00 |
| Example 6 | 1.62 | 0.22 | 0.2% | 1.00 |
| Example 7 | 1.62 | 0.22 | 0.2% | 1.01 |
| Example 8 | 1.62 | 0.22 | 0.2% | 0.98 |
| Example 7-2 | 1.62 | 0.22 | 0.3% | 1.01 |
| Comparative | 1.60 | 0.97 | 7.2% | 0.91 |
| Example 1 | | | | |
| Comparative | 1.61 | 0.95 | 6.9% | 0.93 |
| Example 2 | | | | |
| Comparative | 1.61 | 0.95 | 6.9% | 0.93 |
| Example 3 | | | | |
| Comparative | 1.35 | 0.76 | 5.9% | 0.94 |
| Example 4 | | | | |
| Comparative | 1.35 | 0.76 | 5.9% | 0.94 |
| Example 5 | | | | |
| Comparative | 1.35 | 0.75 | 5.7% | 0.95 |
| Example 6 | | | | |
| Comparative | 1.72 | 0.50 | 1.8% | 1.33 |
| Example 7 | | | | |
| Comparative | 1.72 | 0.50 | 1.8% | 1.31 |
| Example 8 | | | | |

TABLE 4

| | Eop | | | |
|---|---|---|---|---|
| | (mJ/cm²) | Pattern shape | LWR | LER |
| Example 1 | 43 | A | 3.48 | 2.49 |
| Example 2 | 41 | S | 3.35 | 2.38 |
| Example 3 | 40 | S | 3.66 | 2.60 |
| Example 4 | 42 | A | 3.50 | 2.52 |
| Example 5 | 42 | A | 3.51 | 2.52 |
| Example 6 | 41 | A | 3.47 | 2.47 |
| Example 7 | 41 | S | 3.30 | 2.32 |
| Example 8 | 40 | S | 3.50 | 2.49 |
| Example 7-2 | 33 | A | 3.34 | 2.38 |
| Comparative | Occurrence of mixing | | | |
| Example 1 | | | | |
| Comparative | 41 | B | Occurrence of collapse | |
| Example 2 | | | | |
| Comparative | 40 | B | Occurrence of collapse | |
| Example 3 | | | | |
| Comparative | Occurrence of mixing | | | |
| Example 4 | | | | |
| Comparative | 40 | B | Occurrence of collapse | |
| Example 5 | | | | |
| Comparative | 40 | B | Occurrence of collapse | |
| Example 6 | | | | |
| Comparative | 42 | A | 4.21 | 3.06 |
| Example 7 | | | | |
| Comparative | 42 | A | 3.99 | 2.85 |
| Example 8 | | | | |

As shown in the results listed in Table 3, it was confirmed that in Examples 1 to 8 and Example 7-2, the reflectivity could be suppressed as compared with Comparative Examples 1 to 8. In Examples 1 to 8 and Example 7-2, the reflectivity was suppressed to 1% or less. Further, it was confirmed that the resist underlayer films of Examples 1 to 8 and Example 7-2 had an etching rate of about 1 nm/s and thus could be sufficiently used as a mask.

As shown in the results listed in Table 4, it was confirmed that in Examples 1 to 8 and Example 7-2, a resist pattern having a satisfactory pattern shape and high uniformity was formed. The reason for this is considered that the reflectivity of the resist underlayer film was suppressed to 1% or less as listed in Table 3. Since satisfactory results were obtained in all of Examples 1 to 8 and Example 7-2, the composition for forming a resist underlayer film of each example was confirmed to be used as any of a Si-containing resist composition or a Si-free resist composition.

On the contrary, in Comparative Examples 1 and 4, the mixing of the resist underlayer film with the resist composition occurred, and thus the resist pattern could not be formed. The mixing is a phenomenon in which in a case where the resist underlayer film is coated with the resist composition, the resist underlayer film is dissolved in the resist composition, and the resist underlayer film and the resist composition are mixed together. In Comparative Examples 2, 3, 5, and 6, LWR and LER could not be measured due to the occurrence of pattern collapse. In Comparative Examples 7 and 8, both the LWR and the LER were larger than those of the examples.

Hereinbefore, the preferable examples of the present invention have been described, but the present invention is not limited thereto. Additions, omissions, substitutions, and other modifications can be made without departing from the scope of the invention. The present invention is not limited by the foregoing description, but is limited only by the scope of the appended claims.

### REFERENCE SIGNS LIST

10: Substrate
11: Pattern
20: Resist underlayer film
21: Resist underlayer film pattern
30: Resist film
31: Resist pattern

What is claimed is:

1. A composition for forming a resist underlayer film, comprising:
a furan resin;
a thermal acid generator component that generates an acid by heat; and
a solvent.

2. The composition for forming a resist underlayer film according to claim 1, wherein the thermal acid generator component contains a compound which is a quaternary ammonium salt.

3. The composition for forming a resist underlayer film according to claim 1, wherein the thermal acid generator component contains a compound that is decomposed by heat to generate sulfonic acid.

4. The composition for forming a resist underlayer film according to claim 1, further comprising a photoacid generator component that generates an acid upon light exposure.

5. A resist pattern formation method comprising:
forming a resist underlayer film on a substrate using the composition for forming a resist underlayer film according to claim 1;
forming a resist film on the resist underlayer film using a resist composition;
exposing the resist film to light; and
developing the resist film exposed to light to form a resist pattern.

6. A formation method for a resist underlayer film pattern, comprising:
forming a resist pattern by the resist pattern formation method according to claim 5; and
etching the resist underlayer film using the resist pattern as a mask to form a resist underlayer film pattern.

7. A pattern formation method comprising:
forming a resist underlayer film pattern by the formation method for a resist underlayer film pattern according to claim 6; and
etching the substrate using the resist pattern and the resist underlayer film pattern as a mask to form a pattern.
